(19) United States
(12) Patent Application Publication
(10) Pub. No.: US 2016/0084917 A1
(43) Pub. Date: Mar. 24, 2016

(54) APPARATUS AND METHOD FOR DIAGNOSING DEGRADATION OF A HIGH VOLTAGE BATTERY OF A VEHICLE

(71) Applicants: Hyundai Motor Company, Seoul (KR); Kia Motors Corporation, Seoul (KR)

(72) Inventor: Ji Won Nam, Gwangmyeong (KR)

(73) Assignees: KIA MOTORS CORPORATION; HYUNDAI MOTOR COMPANY

(21) Appl. No.: 14/556,182

(22) Filed: Nov. 30, 2014

(30) Foreign Application Priority Data
Sep. 18, 2014 (KR) 10-2014-0124554

(51) Int. Cl. G01R 31/36

(52) U.S. Cl. CPC G01R 31/3679; G01R 31/3655

(57) ABSTRACT

An apparatus and method for diagnosing degradation of a high voltage battery of a vehicle are provided. The method includes calculating an average charging power of a slow charger during a setting interval on slow charging for an electric vehicle and calculating a correction factor based on the average charging power. The method also includes calculating a degree of degradation of the battery based on the average charging power and calculating a final degree of degradation by reflecting the correction factor to the degree of degradation.

### CROSS-REFERENCE TO RELATED APPLICATION(S)

Pursuant to 35 U.S.C. §119(a), this application claims priority to Korean Patent Application No. 10-2014-0124554, filed on Sep. 18, 2014, the disclosure of which is incorporated herein in its entirety by reference.

### BACKGROUND

1. Technical Field

The present disclosure relates to electric vehicle batteries and more particularly to an apparatus and method for diagnosing degradation of a high voltage battery disposed within an electric vehicle.

2. Description of the Prior Art

Stored electrical energy may be the driving force for a vehicle (e.g., in an electric vehicle (EV) or a plug in hybrid electric vehicle (PREV), or the like) equipped with a high voltage battery. The mileage of such vehicles is influenced by the capacity and the status of the high voltage battery. However, due to the nature of vehicle batteries, when consistently used to power vehicles, batteries suffer from a degradation phenomenon in which charging capacity is inevitably reduced. Also, as degradation proceeds, the vehicle suffers from a decrease in mileage and a reduction in battery output used for acceleration, etc. even though the same State Of Charge (SOC) may be displayed.

In conventional related art regarding electric vehicle batteries, even though a battery may have a displayed SOC of more than 90% and the vehicle may be able to use much of the stored charge, battery degradation may have already occurred. Such related art batteries may experience linearly decreasing voltage capacity as the degradation proceeds. Generally, a vehicle battery may be charged using slow charging in order improve battery life, however, since battery charging efficiency, depending on the charging current, may not be reflected in a displayed SOC, an increasing calculation error due to the degree of battery degradation may occur with continued use of the battery.

### SUMMARY

Exemplary embodiments of the present invention provide an apparatus and method for diagnosing degradation of a high voltage battery of a vehicle by diagnosing a degree of degradation by using a charging power of a slow charger for an electric vehicle. Additionally, exemplary embodiments of the present invention provide an apparatus and method for diagnosing degradation of a high voltage battery of a vehicle with improved detection accuracy of a degree of degradation by reflecting the charging efficiency for different charging currents and different degrees of degradation.

According to exemplary embodiments of the present invention, a method for diagnosing degradation of a high voltage battery for a vehicle may include: calculating an average charging power of a slow charger during a setting interval on slow charging for an electric vehicle; calculating a correction factor based on the average charging power, calculating a degree of degradation based on the average charging power; and calculating a final degree of degradation by reflecting the correction factor to the degree of degradation. In addition, the calculation of an average charging power may include: determining whether a detection condition of a charging state of the battery is satisfied; calculating a charging power by measuring a charging voltage and charging current charging the battery when the detection condition of the charging state of the battery; determining whether a detection end condition of the charging state of the battery is satisfied; and calculating an average of charging powers detected by calculating the charging power if the detection end condition of the charging state of the battery is satisfied.

The determination of whether a detection condition of a charging state is satisfied may include: determining whether a cell temperature of the battery is about room temperature, and determining whether the charging voltage is within a particular voltage range. Further, the calculation of a correction factor may include calculating the correction factor that corresponds to the average charging power using a lookup table. The lookup table may include a test result obtained in a state when a temperature of a battery cell is about room temperature and the charging voltage of the slow charger is within a predetermined voltage range, and shows the correction factor for each of charging powers. The calculation of a degree of degradation may include: calculating an average charging current based on the average charging power; and calculating a degree of degradation using the average charging current and a charging state detection time. Furthermore, the calculation of a final degree of degradation may include calculating the final degree of degradation by multiplying the degree of degradation and the correction factor.

An apparatus for diagnosing degradation of a high voltage battery of a vehicle according to an exemplary embodiment of the present invention may include: a battery configured to supply a power source for driving a motor of an electric vehicle; a slow charger disposed within the electric vehicle configured to charge the battery; a meter configured to measure a charging state of the battery; and a degradation diagnosis device configured to: calculate an average charging power by calculating a charging power of the slow charger while the charging state of the battery satisfies a predetermined condition; calculate a correction factor and a degree of degradation based on the average charging power; and calculate a final degree of degradation using the degree of degradation and the correction factor.

The meter may include: a temperature sensor configured to measure a cell temperature of the battery; a voltage sensor configured to measure a charging voltage output from the slow charger; and a current sensor configured to measure a charging current output from the slow charger. Additionally, the degradation diagnosis device may be configured to calculate the charging power while a cell temperature of the battery is about room temperature and a charging voltage of the slow charger is within a particular voltage range. The degradation diagnosis device may be configured to measure a charging voltage and charging current of the slow charger using the meter and calculate the charging power by multiplying the measured charging voltage and charging current. The degradation diagnosis device may be configured to calculate an average charging current form the average charging power, and calculate a degree of degradation using the average charging current and a detection time of the charging state. Further, the degradation diagnosis device may be configured to calculate the final degree of degradation by multiplying the degree of degradation and the correction factor. The degradation diagnosis device may also be configured to output a notification that a replacement and inspection of the battery are required in response to the final degree of degradation exceeding a threshold.

An exemplary embodiment of the present invention may diagnose a degree of degradation of a battery using a charging power of a slow charger for an electric vehicle. Also, an exemplary embodiment of the present invention may improve the detection accuracy of the degree of degradation by reflecting the charging efficiency for different charging currents and different degrees of degradation.

### BRIEF DESCRIPTION OF THE DRAWINGS

The drawings are provided for reference in describing exemplary embodiments of the present invention, and the spirit of the present invention should not be construed only by the accompanying drawings. The above and other objects, features and other advantages of the present invention will be more clearly understood from the following detailed description when taken in conjunction with the accompanying drawings, in which:

FIG. 1 is an exemplary block diagram showing a configuration of an apparatus for diagnosing degradation of a high voltage battery of a vehicle according to an exemplary embodiment of the present invention; and

FIG. 2 is an exemplary flow chart showing a method for diagnosing degradation of a high voltage battery of a vehicle according to an exemplary embodiment of the present invention.

### DETAILED DESCRIPTION

Hereinafter, exemplary embodiments of the present invention will be explained in detail with reference to the accompanying drawings.

It is understood that the term “vehicle” or “vehicular” or other similar term as used herein is inclusive of motor vehicles in general such as passenger automobiles including sports utility vehicles (SUV), buses, trucks, various commercial vehicles, watercraft including a variety of boats and ships, aircraft, and the like, and includes hybrid vehicles, electric vehicles, plug-in hybrid electric vehicles, hydrogen-powered vehicles and other alternative fuel vehicles (e.g. fuels derived from resources other than petroleum). As referred to herein, a hybrid vehicle is a vehicle that has two or more sources of power, for example both gasoline-powered and electric-powered vehicles.

Although exemplary embodiments are described as using a plurality of units to perform the exemplary process, it is understood that the exemplary processes may also be performed by one or plurality of modules. Additionally, it is understood that the term controller/control unit refers to a hardware device that includes a memory and a processor. The memory is configured to store the modules and the processor is specifically configured to execute said modules to perform one or more processes which are described further below.

Furthermore, control logic of the present invention may be embodied as non-transitory computer readable media on a computer readable medium containing executable program instructions executed by a processor, controller/control unit or the like. Examples of the computer readable mediums include, but are not limited to, ROM, RAM, compact disc (CD)-ROMs, magnetic tapes, floppy disks, flash drives, smart cards and optical data storage devices. The computer readable recording medium can also be distributed in network coupled computer systems so that the computer readable media is stored and executed in a distributed fashion, e.g., by a telematics server or a Controller Area Network (CAN).

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items.

The present invention is directed to technology for diagnosing a state of health (SOH) of a vehicle battery, and for diagnosing a degree of degradation of a vehicle battery using a charging power of a slow charger (onboard battery charger, OBC) on slowly charging a high voltage battery for an electric vehicle.

Vehicle battery efficiency may vary based on the level of charging currents used to charge the battery. In general, as the charging current decreases, the battery efficiency increases. As degradation of the battery increases, the amount a battery may be charged tends to decrease linearly. Accordingly, when battery charging is performed in the same condition, the charging efficiency may be different based on a degree of degradation of the battery and the charging current. To compensate for the degradation of a battery and the difference in charging efficiency based on the charging current, the present invention may improve the accuracy of a battery degradation calculation by applying a correction factor for each of different charging powers of a slow charger.

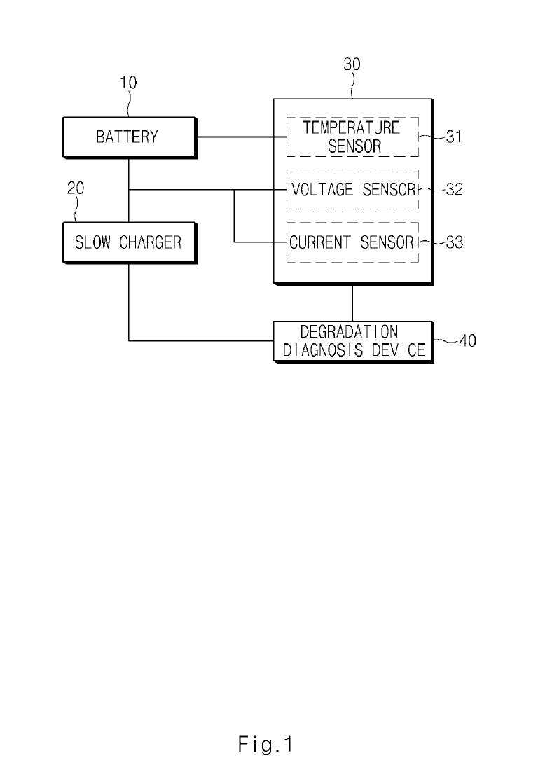

FIG. 1 is an exemplary block diagram showing an apparatus for diagnosing degradation of a high voltage battery of a vehicle according to an exemplary embodiment of the present invention. The apparatus for diagnosing degradation of a high voltage battery of a vehicle may include a battery 10, a slow charger 20, a meter 30 and a degradation diagnosis device 40, (e.g. a controller). A controller may be configured to operate the battery 10, the slow charger 20, the meter 30 and the degradation diagnosis device 40, or alternatively, the controller may be one in the same with the degradation diagnosis device 40.

The battery 10 may be a high voltage battery disposed within an electric vehicle and may be configured to supply a power source for driving a motor of a vehicle. The slow charger 20 may be disposed within an electric vehicle, and may be configured to charge the battery 10 (e.g., by the commercial power supplied from a power supply device (not shown)). The slow charger 20 may be configured to charge the battery 10 by same power. The meter 30 may be configured to sense charging environment information of the battery 10, and may include a temperature sensor 31, a voltage sensor 32 and a current sensor 33. The temperature sensor 31 may be configured to measure the cell temperature of the battery 10, and the, voltage sensor 32 may be configured to measure the charging voltage outputted from the slow charger 20 for charging the battery 10, and the current sensor 33 may be configured to measure the charging current supplied from the slow charger 20 to the battery 10. The meter 30 may also be configured to store the data measured by each of sensors 31 to 33 to a memory (not shown) and manage such data.

The degradation diagnosis device 40 may be configured to determine whether the detection condition of the charging state (e.g., a state of health, SOH) is satisfied when a signal notifying the start of the slow charging is received from the slow charger 20. In other words, the degradation diagnosis device 40 may be configured to determine whether the temperature of the battery cell is about room temperature (for example, about 15° C.-25° C.) using the temperature sensor 31, and determine whether the charging voltage measured by the voltage sensor 32 is within a particular voltage range (e.g.,, about 210V-230V). The particular voltage range may be different based on the characteristic of the battery 10. The degradation diagnosis device 40 may be configured to calculate the charging power (P=I×V) using the charging voltage (V) and the charging current (I) output from the slow charger 20 when the detection condition of the charging state is satisfied. In other words, the degradation diagnosis device 40 may also be configured to detect the charging power of the slow charger 20. The degradation diagnosis device 40 may be configured to store the calculated charging power to a memory (not shown) and manage the calculated charging power.

Furthermore, the degradation diagnosis device 40 may be configured to determine whether the detection end condition of the charging state is satisfied. The degradation diagnosis device 40 may be configured to calculate the charging power of the slow charger 20 using the voltage sensor 32 and the current sensor 33 repeatedly until the detection end condition of the charging state is satisfied (S12-S14). The degradation diagnosis device 40 may be configured to calculate the average charging power of the charging powers calculated in a particular voltage range when the detection end condition of the charging state is satisfied. The degradation diagnosis device 40 may be configured to calculate the correction factor (F) based on the average charging power by referring to a lookup table. The lookup table may include a test result in the battery charging is tested within a particular voltage range when the temperature of the battery cell is about room temperature. The correction factor for each of charging powers shows is described in Table 1.

TABLE 1

| | Average charging power | | |
|---|---|---|---|
| | more than 1.4 kW | more than 3 kW | more than |
| | less than 3 kW | less than 6 kW | 6 kW |
| Correction factor | 1.2 | 1.1 | 1 |

The degradation diagnosis device 40 may be configured to calculate the average charging current within the charging power detection interval using the average charging power. For example, the degradation diagnosis device 40 may be configured to estimate an average charging current

$${I}_{avg} = \frac{{P}_{avg}}{V}$$

by dividing the average power by the charging voltage of the slow charger 20. The degradation diagnosis device 40 may be configured to calculate a degree of degradation using the average charging current I_{avg} and the charging power detection time t. The charging power detection time is understood to mean the duration of time from when the charging power detection condition is satisfied until the time when the charging power detection end condition is satisfied. The degree of degradation D may be defined as in the following Equation 1.

$$D = 100 - \frac{{I}_{avg} \times t}{{C}_{ini}} \qquad Equation 1$$

Wherein Cᵢₙᵢ is an initial charging amount (Ah) of the battery cell.

The degradation diagnosis device 40 may be configured to calculate the final degree of degradation D_{final} of the battery 10 using the calculated degree of degradation D and the correction factor F. The final degree of degradation D_{final} may be represented as shown in the following Equation 2.

D_{final}=D×F Equation 2

The degradation diagnosis device 40 may be configured to output a notification that a replacement and inspection of the battery 10 are required when the final degree of degradation of the battery 10 exceeds a threshold. It should be understood that different thresholds may be appropriate for different batteries and for different vehicles and that such thresholds may be chosen by those skilled in the art, including vehicle manufacturers. The degradation diagnosis device 40 may be implemented to transmit the notification to the mobile terminal (e.g., a phone, a global positioning device, a tablet computer or the like) of the vehicle owner or driver using wireless communication.

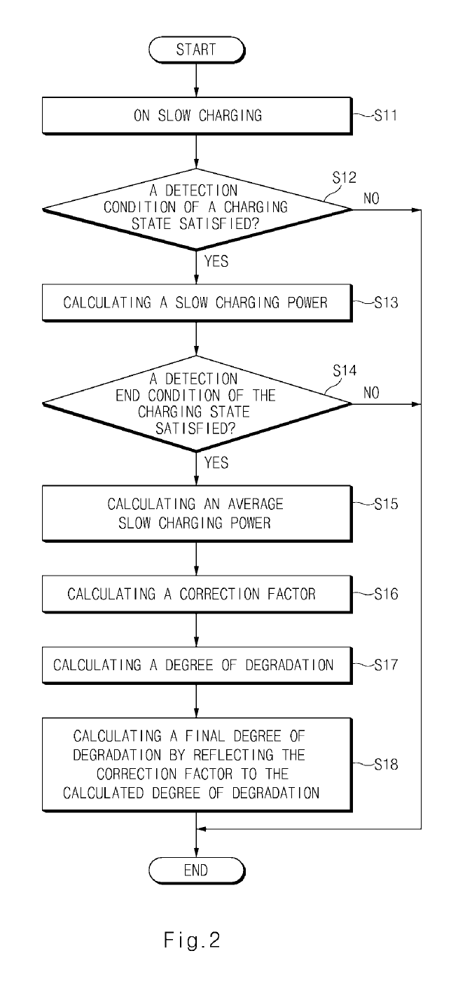

FIG. 2 is an exemplary flow chart showing a method for diagnosing degradation of a high voltage battery of a vehicle according to an exemplary embodiment of the present invention. When slow charging of a vehicle is attempted, the slow charger 20 may be configured to notify the degradation diagnosis device 40 of the start of the slow charging of the battery 10 and perform the slow charging (S11). The degradation diagnosis device 40 may be configured to determine, upon commencing the slow charging, whether the detection condition of the charging state is satisfied using the meter 30 (S12). The degradation diagnosis device 40 may be configured to determine whether the temperature of the battery cell is about room temperature using the temperature sensor 31, and determine whether the charging voltage supplied to the battery 10 is within a particular voltage range using the voltage sensor 32.

During slow charging, the degradation diagnosis device 40 may be configured to calculate (compute) the charging power supplied from the slow charger 20 for charging the battery 10 when the detection condition of the charging state is satisfied (S13). The degradation diagnosis device 40 may be configured to measure the charging voltage and the charging current of the slow charger 20 using the voltage sensor 32 and the current sensor 33 of the meter 30, and calculate the charging power using the measured charging voltage and charging current.

The degradation diagnosis device 40 may be configured to determine whether the detection end condition of the charging state is satisfied by detecting the charging state using the meter 30 after calculating the charging power (S13). In other words, the degradation diagnosis device 40 may be configured to determine whether the temperature of the battery cell departs from (e.g., is less than or greater than) about room temperature, and determine whether the measured charging voltage departs from a particular voltage range using the voltage sensor 32.

Processes S12 to S14 may be performed to detect the charging power supplied to the battery 10 by the slow charger 20 within a particular voltage range. The degradation diagnosis device 40 may be configured to calculate the average of the charging powers detected within a particular voltage range when the detection end condition of the charging state is satisfied (S15). The degradation diagnosis device 40 may be configured to calculate the correction factor that corresponds to the average charging power by referring to a lookup table (S16). The degradation diagnosis device 40 may be configured to calculate the degree of degradation based on the average charging power (S17). The degradation diagnosis device 40 may be configured to calculate the average charging current using the average charging power. The degradation diagnosis device 40 may also be configured to calculate the degree of degradation using the average charging current and the charging power detection time.

The degradation diagnosis device 40 may be configured to calculate the final degree of degradation by reflecting the correction factor to the calculated degree of degradation (S18). After that, the degradation diagnosis device 40 may be configured to output a notification indicating that replacement and inspection of the battery 10 are required when the final degree of degradation exceeds a threshold (e.g., in a form which may be recognized by a user (driver) of the vehicle).

An exemplary embodiment according to the present invention may be implemented by various means, for example, hardware, firmware, software, or a combination of them and the like. In the case of hardware implementations, an exemplary embodiment of the present invention may be implemented by one or more ASICs (Application Specific Integrated Circuits), DSPs (Digital Signal Processors), DSPDs (Digital Signal Processing Devices), PLDs (Programmable Logic Devices), FPGAs (Field Programmable Gate Arrays), processors, controllers, microcontrollers, microprocessors and the like. In the case of implementation by firmware or software, an exemplary embodiment of the present invention may be implemented in the form of a module for performing the above described functions or operations, procedures, functions and the like. Software codes may be stored in a memory unit and may be driven by a processor. The memory unit is located inside or outside the processor, and the data may be exchanged with the processor by various known means.

It is apparent to those skilled in the art that the present invention may be embodied in other specific forms without departing from the features of the present invention. Thus, the above-mentioned detailed description must not be interpreted as restrictive and it must be considered as an example. The scope of the present invention should be defined by the reasonable interpretation of the appended claims, and all the changes within the equivalent scope are included in the scope of the present invention.

What is claimed is:

1. A method for diagnosing degradation of a high voltage battery of a vehicle, comprising:
calculating, by a processor, an average charging power of a slow charger during a setting interval on slow charging for an electric vehicle;
calculating, by the processor, a correction factor based on the average charging power;
calculating, by the processor, a degree of degradation based on the average charging power; and
calculating, by the processor, a final degree of degradation by reflecting the correction factor to the degree of degradation.

2. The method for diagnosing degradation of a high voltage battery of a vehicle according to claim 1, wherein the calculation of an average charging power includes:
determining, by the processor, whether a detection condition of a charging state of the battery is satisfied;
calculating, by the processor, a charging power by measuring a charging voltage and charging current charging the battery when the detection condition of the charging state of the battery;
determining, by the processor, whether a detection end condition of the charging state of the battery is satisfied; and
calculating, by the processor, an average of charging powers detected by calculating the charging power when the detection end condition of the charging state of the battery is satisfied.

3. The method for diagnosing degradation of a high voltage battery of a vehicle according to claim 2, wherein the determination whether a detection condition of a charging state is satisfied includes:
determining, by the processor, whether a cell temperature of the battery is about room temperature; and
determining, by the processor, whether the charging voltage is within a particular voltage range.

4. The method for diagnosing degradation of a high voltage battery of a vehicle according to claim 1, wherein the calculation of the correction factor includes calculating, by the processor, the correction factor that corresponds to the average charging power using a lookup table.

5. The method for diagnosing degradation of a high voltage battery of a vehicle according to claim 4, wherein the lookup table includes a test result of the battery tested in a state when a temperature of a battery cell is about room temperature and the charging voltage of the slow charger is within a predetermined voltage range, and shows the correction factor for each of charging powers.

6. The method for diagnosing degradation of a high voltage battery of a vehicle according to claim 1, wherein the calculation of a degree of degradation includes:
calculating, by the processor, an average charging current based on the average charging power; and
calculating, by the processor, a degree of degradation using the average charging current and a charging state detection time.

7. The method for diagnosing degradation of a high voltage battery of a vehicle according to claim 1, wherein the calculation of the final degree of degradation includes:
calculating, by the processor, the final degree of degradation by multiplying the degree of degradation and the correction factor.

8. An apparatus for diagnosing degradation of a high voltage battery of a vehicle, comprising:
a battery configured to supply a power source for driving a motor of an electric vehicle;
a slow charger disposed in the electric vehicle configured to charge the battery;
a meter configured to measure a charging state of the battery;
a processor configured to:
calculate an average charging power by calculating a charging power of the slow charger while the charging state of the battery satisfies a predetermined condition;
calculate a correction factor and a degree of degradation based on the average charging power; and
calculate a final degree of degradation using the degree of degradation and the correction factor.

9. The apparatus for diagnosing degradation of a high voltage battery of a vehicle according to claim 8, wherein the meter includes:
a temperature sensor configured to measure a cell temperature of the battery;
a voltage sensor configured to measure a charging voltage output from the slow charger; and
a current sensor configured to measure a charging current output from the slow charger.

10. The apparatus for diagnosing degradation of a high voltage battery of a vehicle according to claim 8, wherein the degradation diagnosis device is configured to calculate the charging power while a cell temperature of the battery is about room temperature and a charging voltage of the slow charger is within a predetermined voltage range.

11. The apparatus for diagnosing degradation of a high voltage battery of a vehicle according to claim 8, wherein the degradation diagnosis device is configured to measure a charging voltage and charging current of the slow charger using the meter and calculate the charging power by multiplying the measured charging voltage and charging current.

12. The apparatus for diagnosing degradation of a high voltage battery of a vehicle according to claim 8, wherein the degradation diagnosis device is configured to calculate an average charging current form the average charging power, and calculate a degree of degradation using the average charging current and a detection time of the charging state.

13. The apparatus for diagnosing degradation of a high voltage battery of a vehicle according to claim 8, wherein the degradation diagnosis device is configured to calculate the final degree of degradation by multiplying the degree of degradation and the correction factor.

14. The apparatus for diagnosing degradation of a high voltage battery of a vehicle according to claim 8, wherein the degradation diagnosis device is configured to output a notification that a replacement and inspection of the battery are required in response to the final degree of degradation exceeding a threshold.

15. A non-transitory computer readable medium containing program instructions executed by a processor for diagnosing degradation of a high voltage battery, the computer readable medium comprising:
program instructions that calculate an average charging power of a slow charger during a setting interval on slow charging for an electric vehicle;
program instructions that calculate a correction factor based on the average charging power;
program instructions that calculate a degree of degradation based on the average charging power; and
program instructions that calculate a final degree of degradation by reflecting the correction factor to the degree of degradation.

16. The non-transitory computer readable medium according to claim 15, further comprising:
program instructions that determine whether a detection condition of a charging state of the battery is satisfied;
program instructions that calculate a charging power by measuring a charging voltage and charging current charging the battery if the detection condition of the charging state of the battery;
program instructions that determine whether a detection end condition of the charging state of the battery is satisfied; and
program instructions that calculate an average of charging powers detected by calculating the charging power if the detection end condition of the charging state of the battery is satisfied.

17. The non-transitory computer readable medium according to claim 16, wherein the determining whether a detection condition of a charging state is satisfied includes:
program instructions that determine whether a cell temperature of the battery is room temperature, and checks whether the charging voltage is within a particular voltage range.

18. The non-transitory computer readable medium according to claim 15, wherein the calculation of the correction factor includes calculating the correction factor that corresponds to the average charging power by using a lookup table.

19. The non-transitory computer readable medium according to claim 18, wherein the lookup table includes a test result of the battery tested in a state when a temperature of a battery cell is room temperature and the charging voltage of the slow charger is within a predetermined voltage range, and shows the correction factor for each of charging powers.

20. The non-transitory computer readable medium according to claim 15, wherein the calculation of a degree of degradation includes:
calculating an average charging current based on the average charging power; and
calculating a degree of degradation by using the average charging current and a charging state detection time.
